(19) United States
(12) Patent Application Publication
(10) Pub. No.: US 2026/0156933 A1
(43) Pub. Date: Jun. 4, 2026

(54) SEMICONDUCTOR STRUCTURE AND METHOD OF FORMING THE SAME

(71) Applicant: TAIWAN SEMICONDUCTOR MANUFACTURING COMPANY LTD., HSINCHU (TW)

(72) Inventors: KAU-CHU LIN, TAICHUNG CITY (TW); CHAN-YU HUNG, TAINAN CITY (TW); FEI-YUN CHEN, HSINCHU (TW); CHING-HSIUNG HSU, HSINCHU COUNTY (TW)

(21) Appl. No.: 18/963,835

(22) Filed: Nov. 29, 2024

(51) Int. Cl. H10D 84/85; H01L 23/522; H10D 84/01

(52) U.S. Cl. CPC H10D 84/856; H10D 84/017; H10D 84/0179; H10D 84/0181; H10D 84/0186; H10D 84/0188; H10D 84/0191; H10W 20/498

(57) ABSTRACT

A semiconductor structure and a method of forming the semiconductor structure are provided. The method includes: receiving a semiconductor substrate; forming a first well region and a second well region within the semiconductor substrate; forming a gate dielectric layer in the semiconductor substrate between the first well region and the second well region; forming a first gate electrode over the semiconductor substrate and overlapping the gate dielectric layer; forming a conductive layer in an interconnect structure over the first gate electrode; and electrically connecting the conductive layer to the first gate electrode.

### BACKGROUND

High-voltage transistors are widely used in modern semiconductor devices, e.g., power management integrated circuits (PMIC). The high-voltage transistors are generally designed to operate under a high voltage, e.g., voltage greater than five volts, 10 volts or above, as compared to a low-voltage transistor. A high-voltage transistor is generally formed for withstanding a relatively high breakdown voltage during operation. As such, an isolation structure is often adopted in the channel near the drain terminal for the high-voltage transistor to withstand the high electric field generated by the high voltage supplied to the drain terminal.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIGS. 1A to 1P are cross-sectional views of intermediate stages of a method of forming a semiconductor device, in accordance with some embodiments of the present disclosure.

FIG. 2 shows a plan view of the semiconductor device shown in FIG. 1P, in accordance with some embodiments of the present disclosure.

FIG. 3A shows a distribution of electric field lines in a semiconductor device, in accordance with a comparative embodiment of the present disclosure.

FIG. 3B shows a distribution of electric field lines in a semiconductor device, in accordance with some embodiments of the present disclosure.

FIG. 4A shows cross-sectional view of a semiconductor device, in accordance with some embodiments of the present disclosure.

FIG. 4B shows cross-sectional view of a semiconductor device, in accordance with some embodiments of the present disclosure.

FIG. 5 shows a flowchart of a method of manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

High-voltage (HV) transistors have been widely adopted in power-related applications. An important feature of the HV transistors is its high breakdown voltage in order to withstand a high operation voltage applied to the transistor in both of the switch-on and switch-off states. Generally, a relatively thick gate dielectric layer is arranged between the channel and the gate electrode to withstand a high operation voltage. Further, a buried isolation region, which is usually referred to as a shallow trench isolation (STI) structure, is employed between the drain terminal and the gate dielectric layer or between the source terminal and the gate dielectric layer to increase the capability of the high breakdown voltage of the HV transistor. However, the goal of the high-voltage operation with such arrangement is achieved at the cost of the lifted turn-on resistance R_{ds(ON)} between the drain terminal and the source terminal and the decreased operation current during the turn-on state of the HV transistor.

The present disclosure discusses a new HV transistor structure to maintain the capability of high-voltage operation while improving the turn-on resistance R_{ds(ON)} between the drain terminal and the source terminal. A field plate is proposed to serve as an extension of the gate electrode and electrically coupled to the gate electrode through electrical connections in an interconnect structure. During the switch-off state when the gate electrode is biased to a low voltage, the field plate can provide an additional area of the low voltage in the HV transistor. The electric field between the high-voltage drain terminal and the low-voltage gate electrode can be adjusted so that the areas with a peak electric field intensity can be reduced. During the turn-on state, the turn-on resistance R_{ds(ON)} between the drain terminal and the source terminal can be reduced since the intervening STI structure between the gate dielectric layer and the drain terminal is removed, reducing the effective channel length of the HV transistor. Further, the proposed HV transistor structure can be formed without the bulky STI structure between the gate dielectric layer and the drain terminal, and therefore the device footprint can be decreased. The performance and processing cost of the HV transistor can thus be improved.

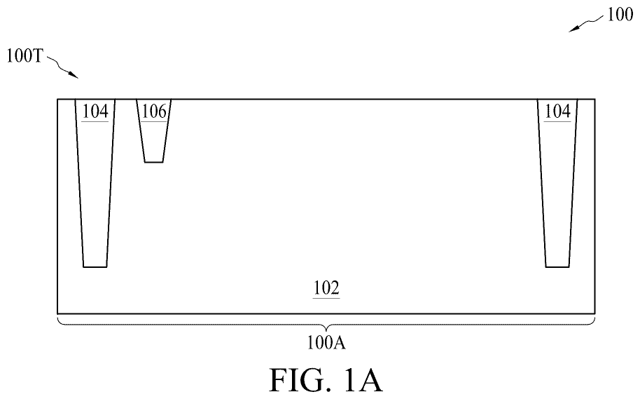

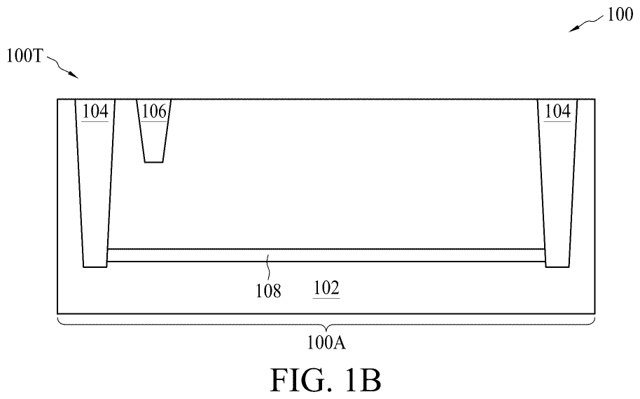

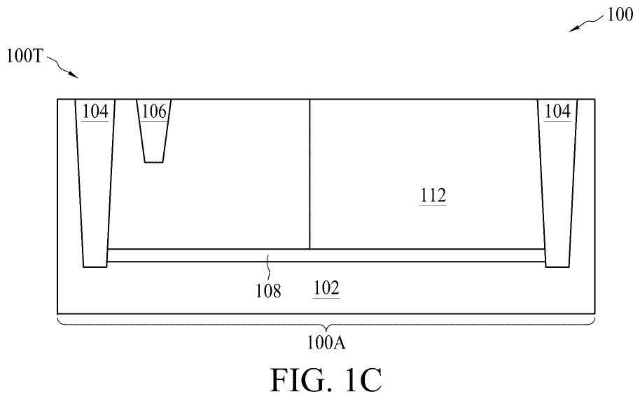

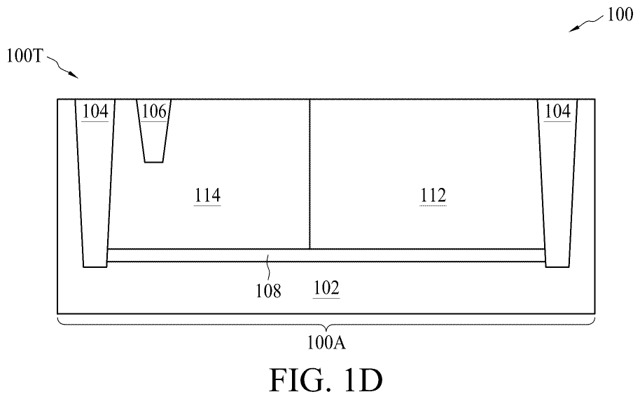

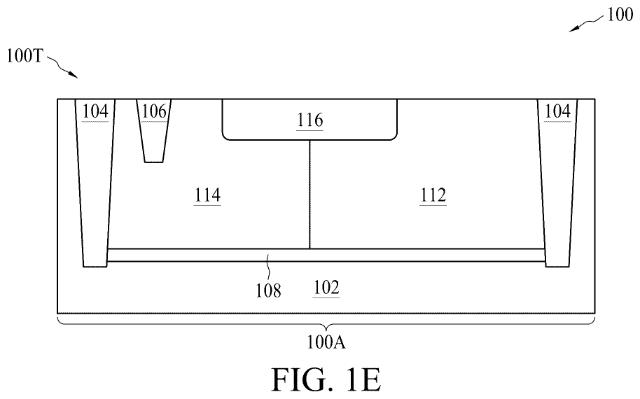

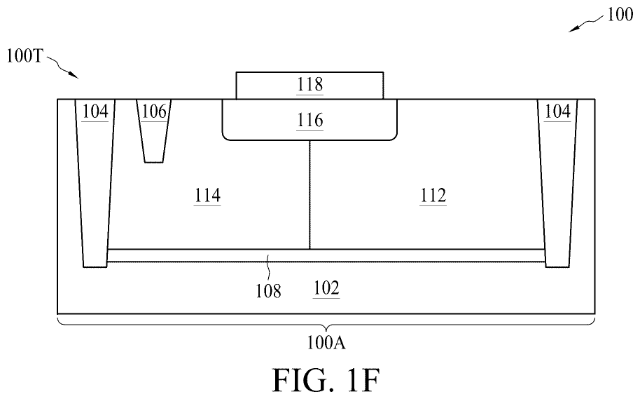

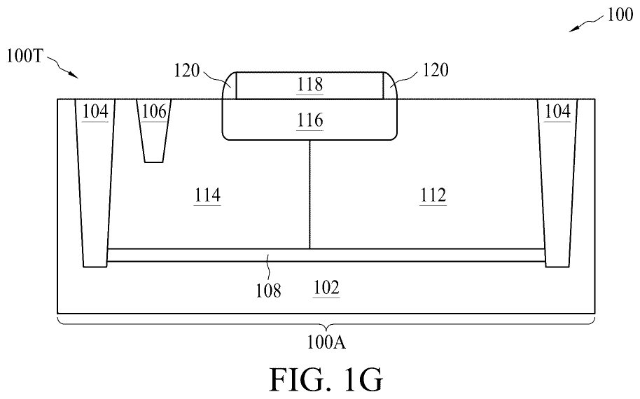

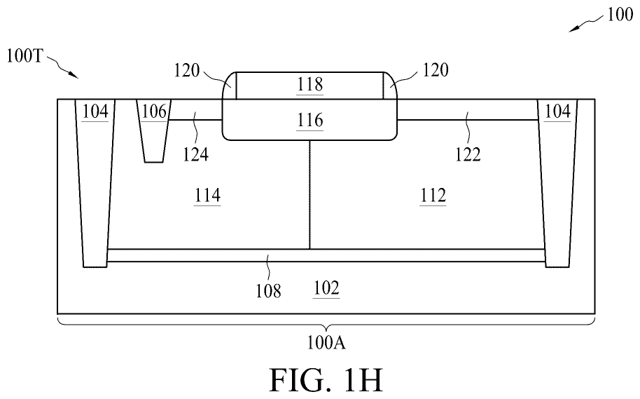

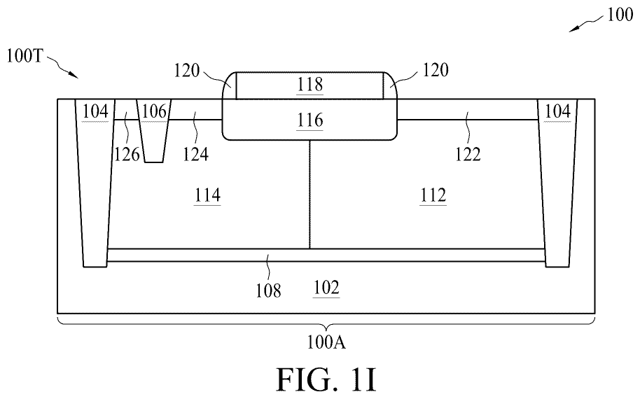

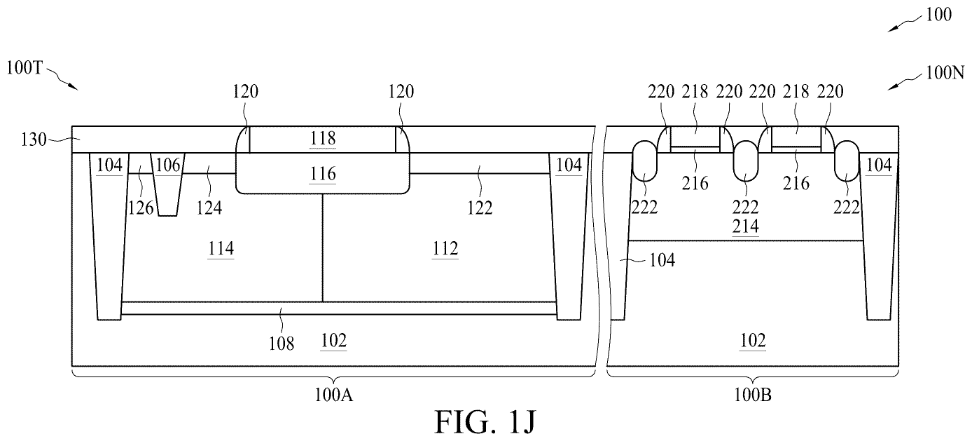

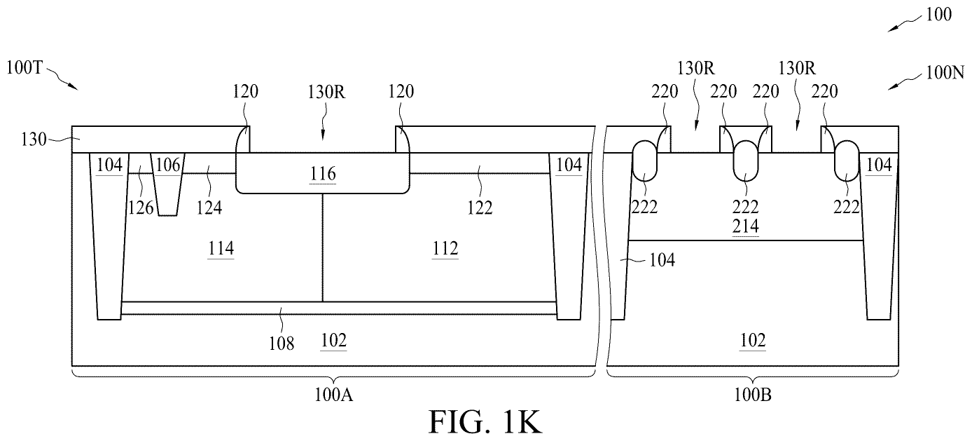

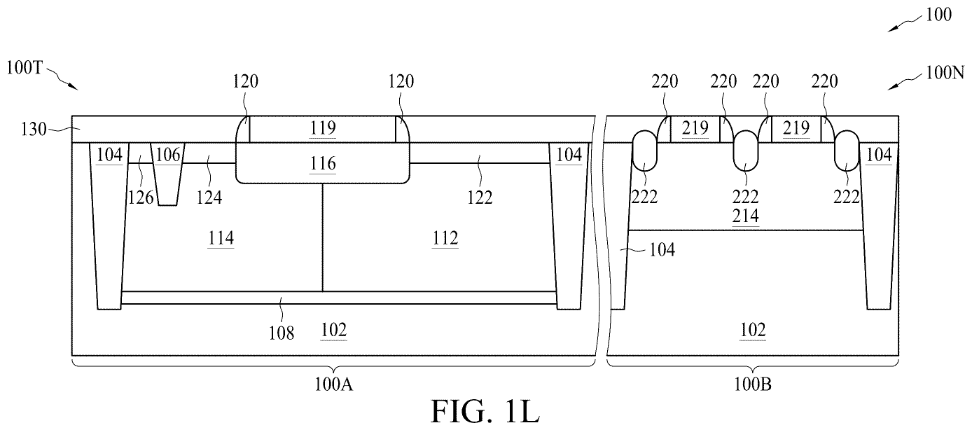

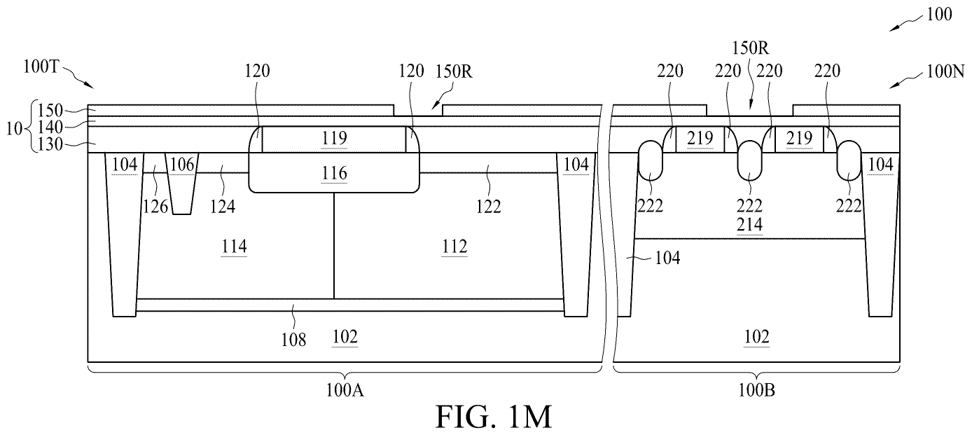

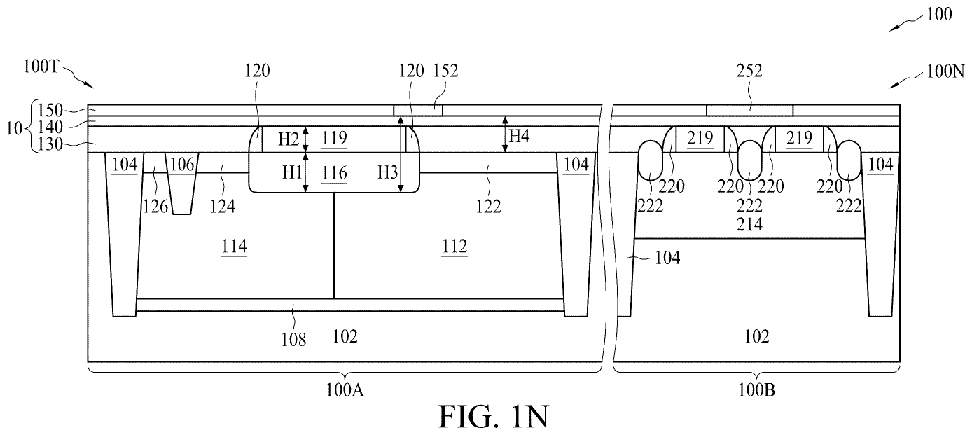

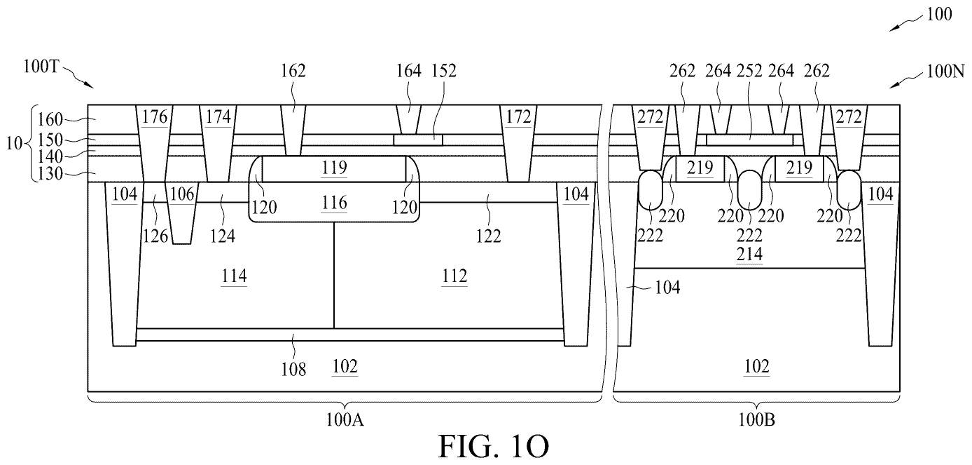

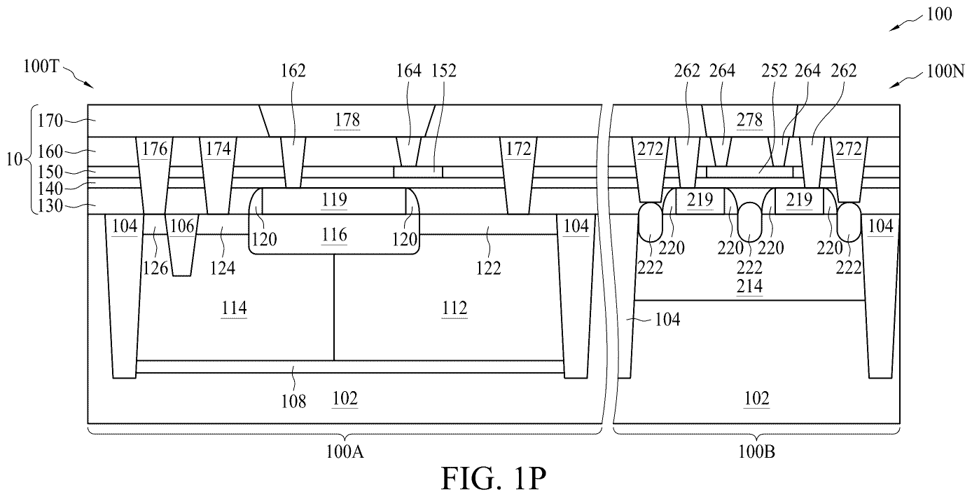

FIGS. 1A to 1P are cross-sectional views of intermediate stages of a method of forming a semiconductor device 100, in accordance with some embodiments of the present disclosure. In some embodiments, the semiconductor device 100 includes at least two zones 100A and 100B (see FIG. 1J) for accommodating transistors of different operation voltages. The transistors of the semiconductor device 100 may include metal-oxide semiconductor (MOS) field-effect transistors (FET). In some embodiments, the zone 100A is referred to herein as an HV zone, and includes HV transistors, e.g., an exemplary HV transistor 100T. In some embodiments, the zone 100B is referred to herein as a non-HV (NHV) zone, e.g., one or more of medium-voltage (MV) zones or low-voltage (LV) zones, and includes MV transistors or LV transistors, e.g., an exemplary NHV transistor 100N (see FIG. 1J). Throughout the present disclosure, the term “HV transistor” refers to a transistor, e.g., a bipolar CMOS DMOS (BCD) transistor, that operates in a relatively high voltage range, e.g., the voltage may be greater than 5 volts, 10 volts, 20 volts, 30 volts or higher, and terms “NHV transistor” refers to an MV or LV transistor that operates in a medium or low operation voltage range, e.g., the operation voltage lower than that of the HV transistor, such as lower than about 5 volts. In some embodiments, the operation voltage ranges for the various types of transistors, e.g., the HV transistor, the MV transistor, and the LV transistor, are varying based on different applications. In some embodiments, the operation voltage of the HV transistor is no less than that of the NHV transistor. The category of the three types of transistors as discussed above is shown for illustration purposes. The semiconductor device 100 can include more than two zones for accommodating more than two types of transistors of the respective operation voltage ranges.

Referring to FIG. 1A, a semiconductor substrate 102 is provided or formed. In some embodiments, the semiconductor substrate 102 includes semiconductor material such as bulk silicon. In some embodiments, the semiconductor substrate 102 includes other semiconductor materials, such as silicon germanium, silicon carbide, gallium arsenide, or the like. In the present embodiment, the semiconductor substrate 102 is a P-type semiconductive substrate (acceptor type). In some other embodiments, an N-type semiconductive substrate (donor type) 102 can be used. Alternatively, the semiconductor substrate 102 includes another elementary semiconductor, such as germanium; a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. In yet another embodiment, the semiconductor substrate 102 includes portions to form a semiconductor-on-insulator (SOI) substrate. In other alternatives, the semiconductor substrate 102 may include a doped epitaxial layer, a gradient semiconductor layer, and/or a semiconductor layer overlaying another semiconductor layer of a different type, such as a silicon layer on a silicon germanium layer.

A plurality of isolation regions 104 are formed on the upper surface of the semiconductor substrate 102. The isolation regions 104 may include electrically insulating materials or dielectric materials, such as silicon oxide; however, other dielectric materials, e.g., silicon nitride, silicon oxynitride, silicon carbide, silicon oxynitride, or the like, are also possible for forming the isolation regions 104. In some embodiments, the isolation regions 104 are referred to as shallow trench isolation (STI) structures.

In an exemplary procedure of forming the isolation regions 104, a plurality of trenches (not separately shown) are etched from the upper surface of the semiconductor substrate 102. The trenches are formed on the upper surface in the HV zone 100A and the NHV zone 100B (see FIG. 1J). The trenches may have substantially equal depths measured from the upper surface. The trenches may be formed using a dry etch, a wet etch, a reactive ion etch (RIE), a combination thereof, or the like. The trenches are filled with the dielectric materials to form the isolation regions 104 using, e.g., chemical vapor deposition (CVD), physical vapor deposition (PVD), atomic layer deposition (ALD), oxidation, nitridation, in-situ steam generation (ISSG), spin-on coating, or other suitable deposition methods.

After the dielectric material of the isolation region 104 fills the trenches, a planarization operation, e.g., chemical mechanical polishing (CMP) or mechanical grinding, may be adopted to remove excess dielectric materials over the upper surface of the semiconductor substrate 102 and level the surface of the isolation regions 104 with the upper surface of the semiconductor substrate 102.

In some embodiments, the isolation regions 104 are formed within the HV zone 100A and at the boundary of the HV zone 100A and the NHV zone 100B for defining the boundary of different doped regions or well regions in the zones 100A, 100B or the boundary of each transistor in the respective zones 100A, 100B. The isolation regions 104 are also configured to electrically isolate adjacent transistors.

An isolation region 106 is formed within an active area (or referred to as an oxide definition (OD) area). The isolation region 106 serves as an isolation region in the HV transistor 100T for improving the performance in a high operation voltage. According to some embodiments, the isolation region 106 has a depth less than a depth of the isolation regions 104.

Referring to FIG. 1B, a well region 108 is formed in the semiconductor substrate 102. The well region 108 is formed in a lower portion at a depth of the semiconductor substrate 102. The well region 108 is also referred to herein as a buried layer. Furthermore, the well region 108 is configured as an isolation layer such that noise resulting from different circuits arranged in other areas (not shown) of the semiconductor substrate 102 may be shielded by the well region 108. Thus, the electrical performance of the HV transistor 100T may be ensured. In an embodiment, the well region 108 is doped with an N-type dopant in a P-type semiconductor substrate 102. Thus, the well region 108 is also referred to herein as a deep N-well. In some embodiments, the well region 108 is present only in the HV zone 100A for the HV transistors. In some embodiments, the NHV zone 100B are not used for accommodating HV transistors, and thus are free of any of deep well regions. The depth and profile of the well region 108 are controlled by the recipes of the ion implantation operation. In some embodiments, the ion implantation operation may use N-type dopants, e.g., phosphor, with an implant dose in a range between about 1×10¹⁰ and about 1×10¹⁸ atoms/cm².

Referring to FIG. 1C, a well region 112 is formed in the semiconductor substrate 102 over the well region 108. The well region 112 is formed as a doped region at the top portion of the semiconductor substrate 102. In some embodiments, the well region 112 is formed over the underlying well region 108. In some embodiments, the well region 112 is an N-type well region. The well region 112 may be formed using an ion implantation operation. The depth and profile of the well region 112 are controlled by the recipes of the ion implantation operation. In some embodiments, the ion implantation operation may use N-type dopants, e.g., phosphor and arsenic, with an implant dose in a range between about 1×10¹⁰ and about 1×10¹⁸ atoms/cm².

Referring to FIG. 1D, a well region 114 is formed in the semiconductor substrate 102 adjacent to the well region 112. The well region 114 is formed as a doped region at the top portion of the semiconductor substrate 102. In some embodiments, the well region 114 is formed over the underlying well region 108. In some embodiments, the well region 114 is a P-type well region. The well region 114 may be formed using an ion implantation operation. The depth and profile of the well region 114 are controlled by the recipes of the ion implantation operation. In some embodiments, the ion implantation operation may use P-type dopants, e.g., boron, with an implant dose in a range between about 1×10¹⁰ and about 1×10¹⁸ atoms/cm². The well region 114 laterally surrounds the isolation region 106.

FIG. 1E shows a formation of a gate dielectric layer 116 in the semiconductor substrate 102. In some embodiments, the material layer of the gate dielectric layer 116 includes silicon oxide, silicon nitride, silicon oxynitride or other suitable dielectric materials. The gate dielectric layer 116 may be formed by etching a recess in the semiconductor substrate 102 and depositing a dielectric material using CVD, PVD, ALD, ISSG or other suitable deposition methods. Alternatively, thermal oxidation can be used to form the gate dielectric layer 116.

Referring to FIG. 1F, A gate electrode 118 is formed over the gate dielectric layer 116. The gate electrode 118 may include a conductive material, such as doped silicon. The gate electrode 118 may serve as a dummy gate electrode or sacrificial gate electrode at the moment, and will be replaced with a functional gate electrode or metal gate electrode (see an electrode gate 119 shown in FIG. 1L). The gate electrode 118 may be formed by initially depositing a conductive material in a blanket manner over the upper surface of the semiconductor substrate 102, followed by a patterning operation to form the gate electrode 118. According to some embodiments, the gate electrode 118 overlaps the underlying gate dielectric layer 116. Further, the gate dielectric layer 116 may have a width greater than the gate electrode 118.

Referring to FIG. 1G, gate spacers 120 (or sidewall spacers) are formed on sidewalls of the gate electrode 118 in the HV zone 100A. In some embodiments, the gate spacers 120 are formed of dielectric layers, such as oxide, nitride, carbide, oxynitride, high-k dielectric materials, a combination thereof, or other suitable dielectric materials. In some embodiments, the gate spacers 120 include a single layer or multilayer structure. The gate spacers 120 may be formed by depositing one or more layers of dielectric materials in a conformal manner, followed by etching the horizontal portion of the dielectric materials. The vertical portion of the dielectric materials is left on the sidewalls of the gate electrodes 118 to thereby form the gate spacers 120.

Referring to FIG. 1H, in some embodiments, a drain region 122 and a source region 124 are formed in the semiconductor substrate 102 after the gate electrode 118 is formed. The drain region 122 is arranged between the gate dielectric layer 116 and an adjacent isolation region 104. The source region 124 is arranged between the gate dielectric layer 116 and the adjacent isolation region 106. The drain region 122 and the source region 124 may include a dopant of a conductivity type, e.g., N-type, same as that of the well region 112. In some other embodiments, the drain region 122 and the source region 124 include a dopant of the other conductivity type, e.g., P-type, different from that of the well region 112. In some embodiments, a channel of the HV transistor 100T is formed between the drain region 122 and the source region 124 along a path along the sides and the bottom of the gate dielectric layer 116. The drain region 122 and the source region 124 have a dopant concentration greater than that of the well region 112 and 114, and may be doped regions formed by an ion implantation operation with an implant dose between about 10¹⁰ atoms/cm2 and about 10¹⁸ atoms/cm². Throughout the present disclosure, source/drain region(s) may refer to a source or a drain, individually or collectively dependent upon the context.

Referring to FIG. 1I, a doped region 126 is formed in the semiconductor substrate 102 after the gate electrode 118 is formed. The doped region 126 is arranged between the isolation region 106 and an adjacent isolation region 104. The doped region 126 may include a dopant of a conductivity type, e.g., P-type, different from that of the drain region 122 or the source region 124. In some embodiments, the doped region 126 serves as a body contact to receive a biased voltage for the semiconductor substrate 102. The doped region 126 may be formed by an ion implantation operation with an implant dose between about 10¹⁰ atoms/cm² and about 10¹⁸ atoms/cm².

FIG. 1J shows a formation of one or more NHV transistors 100N in the NHV zone 100B. The semiconductor device 100 includes features in the NHV zone 100B similar to those formed in the HV zone 100A, such as the semiconductor substrate 102 and the isolation regions 104. The HV transistor 100T operates under a first biasing voltage greater than a second biasing voltage under which the NHV transistor 100N operates. As discussed previously, the HV zone 100A and the NHV zone 100B are different zones of a shared semiconductor substrate 102. Further, the NHV transistors 100N may be a non-planar transistor, e.g., a FinFET, a gate-all-around FET (GAAFET), a nanowire FET, a nanosheet FET, or other suitable non-planar FET devices. The HV transistor 100T is a planar transistor. Some of the operations for forming the HV transistor 100T may be similar to those for forming the NHV transistors 100N, and some other operations may not. The operations shared by the HV transistor 100T and the NHV transistor 100N are performed for forming the HV transistor 100T and the NHV transistor 100N at the same time with the same operation.

For example, although not explicitly illustrated, the isolation regions 104 formed in the NHV zone 100B can have materials and methods of forming similar to those of the isolation regions 104 formed in the HV zone 100A. Thus, the isolation regions 104 arranged in the HV zone 100A and the NHV zone 100B can be formed at the same time using the same forming operations (e.g., etching, deposition, planarization, or the like).

According to some embodiments, a plurality of fin structures (not separately shown) are formed in the NHV zone 100B of the semiconductor substrate 102. The fin structures may be formed prior or subsequent to the formation of the well regions 112 and 114. The fin structures are forming using an etching operation, such as a dry etch, a wet etch, an RIE, or the like.

According to some embodiments, a well region 214 is formed in the NHV zone 100B between the adjacent isolation regions 104. In some embodiments, the well region 108 is absent from the NHV zone 100B, and the well region 214 is formed after the well region 108 is formed in the HV zone 100A. In some embodiments, the well region 214 is a P-type well region. The well region 214 may be formed using an ion implantation operation similar to that used for forming the well regions 112 and 114. The depth and profile of the well region 214 are controlled by the recipes of the ion implantation operation. In some embodiments, the ion implantation operation may use P-type dopants, e.g., boron, with an implant dose in a range between about 1×10¹⁰ and about 1×10¹⁸ atoms/cm². The ion implantation operation of the well region 214 may be performed along with that of the well region 114 if their ion implantation recipes are the same, or may be performed separately if their ion implantation recipes differ from each other. The order of forming the well regions 112, 114 and 214 are interchangeable.

A material layer of one or more gate dielectric layers 216 is deposited over the fin structures. Further, another material layer of one or more gate electrodes 218 are formed over the gate dielectric layers 216. The gate dielectric layers 216 and the respective gate electrodes 218 are formed through a patterning operation on the material layers of the gate dielectric layers 216 and the gate electrodes 218. The materials of the gate dielectric layers 216 and the gate electrodes 218 may be similar to those of the gate dielectric layer 116 and the gate electrode 118, respectively. According to some embodiments, the gate electrodes 218 may be formed along with the formation of the gate electrode 118 using the same deposition and patterning operations. The gate electrodes 118 and 218 may be formed at the same level over the semiconductor substrate 102 with substantially equal heights. Subsequently, a gate spacer 220 is formed on the gate electrodes 218 through deposition and patterning operations. According to some embodiments, the gate spacers 220 may be formed along with the formation of the gate spacers 120 using the same deposition and patterning operations. The gate spacers 118 and 218 may be formed at the same level over the semiconductor substrate 102 with substantially equal heights.

A plurality of source/drain regions 222 are formed on the fin structures between the gate electrodes 218. The source/drain regions 222 may be formed by initially etching a portion of the fin structures not covered by the gate electrodes 218 and the gate dielectric layer 220, followed by an epitaxy operation to grow the source/drain regions on two sides of the gate electrodes 218.

According to some embodiments, after the formation of the source/drain regions 222 in the NHV zone 100B, a first interlayer dielectric (ILD) layer 130 is deposited over the semiconductor substrate 102 across the HV zone 100A and the NHV zone 100B. The first ILD layer 130 may include a dielectric material, such as silicon oxide. Other dielectric materials, such as silicon nitride, silicon oxynitride, or silicon carbide may also be used in the first ILD layer 130. The first ILD layer 130 may be deposited using CVD, PVD, ALD, spin coating, or other suitable deposition operations. According to some embodiments, a planarization operation, e.g., chemical mechanical polishing (CMP), mechanical grinding, or other etching operation, may be used to planarize the upper surface of the first ILD layer 130 and level the upper surface of the first ILD layer 130 with the upper surface of the gate electrodes 118 and 218.

Referring to FIG. 1K, an etching operation is performed to remove the gate electrodes 118 and 218. According to some embodiments, the etching operation also removes the gate dielectric layers 216. The etching operation may include a dry etch, a wet etch, an RIE, or the like. A plurality of recesses 130R are formed in the first ILD layer 130 in the HV zone 100A and the NHV zone 100B accordingly. A portion of an upper surface of the gate dielectric layer 116 in the HV zone 100A or a portion of the semiconductor substrate 102 in the NHV zone 100B are thus exposed.

Referring to FIG. 1L, a gate electrode 119 is formed in the recess 130R in the HV zone 100A. The gate electrode 119 may include a plurality of layers formed of conductive materials, such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au), titanium nitride (TiN), tantalum nitride (TaN), a combination thereof, or other suitable materials. According to some embodiments, a high-k dielectric layer is deposited over the gate dielectric layer 116 before the deposition of the conductive materials of the gate electrode 119.

According to some embodiments, one or more gate electrodes 219 are formed in the recess 130R in the NHV zone 100B. The gate electrode 219 may include a plurality of layers formed of conductive materials, such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au), titanium nitride (TiN), tantalum nitride (TaN), a combination thereof, or other suitable materials. According to some embodiments, an interfacial layer and a high-k dielectric layer are deposited in the recesses 130R before the deposition of the conductive materials of the gate electrode 219. According to some embodiments, the gate electrode 119 and the gate electrodes 219 share one or more conductive layers in common, and these common conductive layers are deposited at the same time using the shared deposition operation.

Referring to FIG. 1M a second ILD layer 140 is deposited over the first ILD layer 130. The material, configuration and method of forming for the second ILD layer 140 may be similar to those for the first ILD layer 130. A third ILD layer 150 is deposited over the second ILD layer 140. The material, configuration and method of forming for the third ILD layer 150 may be similar to those for the first ILD layer 130 or the second ILD layer 140. A plurality of recesses 150R are formed in the third ILD layer 150. The recesses 150R may be formed using lithography and etching operations. The etching operation may include a dry etch, a wet etch, an RIE, or the like.

FIG. 1N shows a formation of a conductive layer 152 and a conductive line 252 in the recesses 150R of the HV zone 100A and the NHV zone 100B, respectively. The formations of the conductive layer 152 and the conductive line 252 may be performed at the same time using the same deposition operations, e.g., CVD, PVD, ALD, or other suitable deposition operations. The conductive layer 152 and the conductive line 252 are formed of the same material. The conductive layer 152 and the conductive line 252 may be formed of metal-based materials with a high electrical resistance, such as titanium-based metal, aluminum-based metal, nickel-chromium, or the like. In some embodiments, the conductive layer 152 and the conductive line 252 are formed of titanium nitride. According to some embodiments, the conductive layer 152 and the conductive line 252 include a resistance greater than about 750 Ω or Ω/□. According to some embodiments, the conductive layer 152 is arranged on a side of the gate electrode 119 opposite to the isolation region 106. The conductive layer 152 and the conductive line 252 are formed in a same tier, i.e., the third ILD layer 150, of an interconnect structure 110 over the HV transistor 100T and the NHV transistor 100N.

As discussed previously, as illustrated in FIG. 1N, the conductive line 252 is disposed directly over the NHV transistor 100N. However, this embodiment is not to be limiting. The conductive line 252 can be disposed in other locations in the NHV zone 100B but not directly over the NHV transistor 100N.

According to some embodiments, the conductive layer 152 is arranged horizontally adjacent to the conductive via 162. In other words, the conductive layer 152 is arranged in a same tier of the interconnect structure 110 as the conductive via 162.

According to some embodiments, the gate dielectric layer 116 of the HV transistor 100T in the HV zone 100A has a thickness H1 greater than the thickness of the gate dielectric layer 216 in the NHV zone 100B. For example, the gate dielectric layer 116 has a thickness in a range between about 600 angstrom and about 1000 angstrom, e.g., 850 angstrom. According to some embodiments, the gate dielectric layer 216 has a thickness less than about 50 angstrom, less than about 20 angstrom, or less than about 10 angstrom.

According to some embodiments, the gate electrode 119 has a thickness H2 in a range between about 300 angstrom and about 500 angstrom, such as 400 angstrom. According to some embodiments, a distance H3 between a bottom surface of the conductive layer 152 and a bottom surface of the gate dielectric layer 116 is in a range between about 1200 angstrom and about 1500 angstrom, e.g., 1300 angstrom. According to some embodiments, a dimension ratio H3/H1 is in a range between about 1.2 and about 2.5. a distance H4 between a bottom surface of the conductive layer 152 and an upper surface of the semiconductor substrate 102 is in a range between about 350 angstrom and about 550 angstrom, e.g., 450 angstrom. On one hand, if the distance H4 is greater than about 550 angstrom, the influence of the conductive layer 152 on the current flowing in the channel of the semiconductor device 100 is not significant. On the other hand, if the distance H4 is less than about 350 angstrom, the new electrical field introduced by the conductive layer 152 may adversely impact the current flowing in the channel of the semiconductor device 100.

Referring to FIG. 1O, a fourth ILD layer 160 is deposited over the third ILD layer 150. The material, configuration and method of forming for the fourth ILD layer 160 may be similar to those for the first ILD layer 130, the second ILD layer 140 or the third ILD layer 150. A plurality of conductive vias are formed through the first ILD layer 130, the second ILD layer 140, the third ILD layer 150 or the fourth ILD layer 160. For example, a conductive via 162 is formed through the fourth ILD layer 160, the third ILD layer 150 and the second ILD layer 140, and electrically connected to the gate electrode 119, and a conductive via 164 is formed through the fourth ILD layer 160 and electrically connected to the conductive layer 152. Similarly, conductive vias 172, 174 and 176 are formed through the fourth ILD layer 160, the third ILD layer 150, the second ILD layer 140 and the first ILD layer 130, and electrically connected to the drain region 122, the source region 124 and the doped region 126. Additionally, conductive vias 262 are formed through the fourth ILD layer 160, the third ILD layer 150 and the second ILD layer 140, and electrically connected to the respective gate electrodes 219, and conductive vias 264 are formed through the fourth ILD layer 160 and electrically connected to two ends of the conductive line 252. Conductive vias 272 are formed through the fourth ILD layer 160, the third ILD layer 150 and the second ILD layer 140 and extending into the first ILD layer 130, and electrically connected to the respective source/drain regions 222.

According to some embodiments, the conductive vias 162, 164, 172, 174, 176, 262, 264 and 272 are formed of a conductive material, such as tungsten, titanium, tantalum, aluminum, copper, gold, silver, or the like. The conductive vias 162, 164, 172, 174, 176, 262, 264 and 272 may be formed by etching vias from the upper surface of the fourth ILD layer 160 to expose the upper surfaces of the gate electrode 119, the conductive layer 152, the drain region 122, the source region 124, the doped region 126, the gate electrodes 219, the conductive line 252 and the source/drain regions 222, respectively. A conductive material of the conductive vias 162, 164, 172, 174, 176, 262, 264 and 272 is deposited in the etched vias and over the upper surface of the fourth ILD layer 160. According to some embodiments, a planarization operation, e.g., CMP, is performed to remove the excess portion of the conductive material and level the upper surfaces of the conductive vias 162, 164, 172, 174, 176, 262, 264 and 272 with the upper surface of the fourth ILD layer 160.

Referring to FIG. 1P, a fifth ILD layer 170 is deposited over the fourth ILD layer 160. The material, configuration and method of forming for the fifth ILD layer 170 may be similar to those for the ILD layers 130, 140, 150 and 160. A plurality of recesses (not separately shown) is etched in the fifth ILD layer 170. A conductive material, such as tungsten, titanium, tantalum, aluminum, copper, gold, silver, or the like, is deposited in the recesses to form a conductive line 178 in the HV zone 100A and a conductive line 278 in the NHV zone 100B. The conductive line 178 electrically connects the gate electrode 119 to the conductive layer 152 through the conductive vias 162 and 164, respectively. Similarly, the conductive line 278 is electrically connected to the two ends of the conductive line 252 through the respective conductive vias 264.

According to some embodiments, the ILD layers 140, 150, 160, and 170 (optionally including the first ILD layer 130) constitute the interconnect structure 110 over the HV transistor 100T and the NHV transistor 100N. The conductive vias 162, 164, 172, 174, 176, 262, 264 and 272 and the conductive lines 178, 252, 278 are interconnected within the interconnect structure 110 for providing interconnections between overlying circuits and the HV transistor 100T and the NHV transistor 100N. According to some embodiments, as discussed previously, the conductive layer 152 and the conductive line 252 are formed of a high-resistance conductive material, while the conductive vias 162, 164, 172, 174, 176, 262, 264 and 272 and the conductive lines 178 and 278 are formed of a low-resistance conductive material. As a result, the conductive layer 152 and the conductive line 252 are formed of a material different from that of the 162, 164, 172, 174, 176, 262, 264 and 272 and the conductive lines 178 and 278.

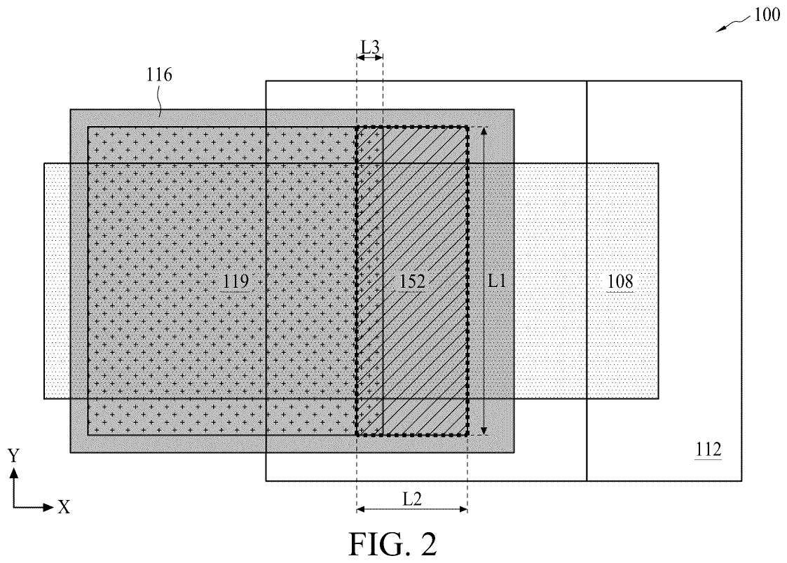

FIG. 2 shows a plan view of the semiconductor device 100, in accordance with some embodiments of the present disclosure. Referring to FIG. 2, the conductive layer 152 may include a length L1 greater than or substantially equal to the length of the gate electrode 119 in the direction of Y-axis. The conductive layer 152 with a greater length L1 may provide the conductive layer 152 with a larger conductive area over the surface of the substrate 102, which aids in rearrangement of the electrical field around the gate dielectric layer 116 for reducing the risk of breakdown. Further, the conductive layer 152 has a width L2 in the direction of X-axis and overlaps the gate electrode 119 with a length L3 in the direction of X-axis. According to some embodiments, the length L2 is in a range between about 0.1 μm and 0.5 μm, such as 0.3 μm. According to some embodiments, a ratio L3/L2 is in a range between about 0.05 and about 0.8. With the overlapped portion between the conductive layer 152 and the gate electrode 119, the conductive layer 152 serves as a field plate functioning as an extension of the gate electrode 11 but does not increase the actual dimensions of the gate electrode 119. According to some embodiments, the length L3 is substantially zero, which means the conductive layer 152 meets or is aligned with the gate electrode 119 without overlap between them, and the effect of the conductive layer 152 serving as an extension of the gate electrode 119 is still maintained. Therefore, the function of the gate electrode 119 for improving the electrical performance of the HV transistor 100T can be strengthened without sacrificing the additional footprint of the gate electrode 119.

According to some embodiments, the gate dielectric layer 116 overlaps the entire gate electrode 119 and the conductive layer 152 in both X-axis and Y-axis from a top-view perspective. According to some embodiments, the gate electrode 119 includes two opposite lateral sides extending in the Y-axis, and the conductive layer 152 overlaps only one (e.g. the right side) of the two opposite lateral sides from a top-view perspective. According to some embodiments, the gate dielectric layer 116 is non-overlapped with the gate electrode 119 from a top-view perspective.

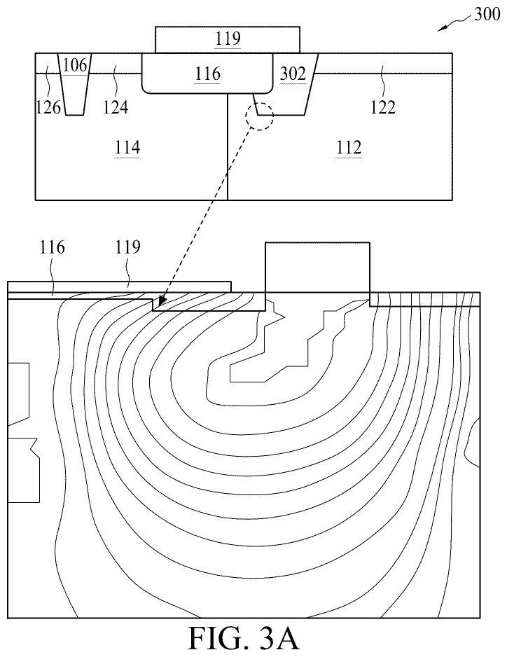

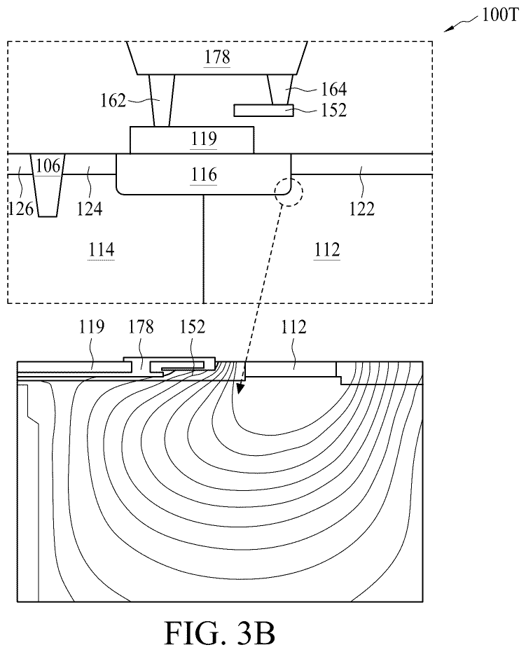

FIG. 3A shows a distribution of electric field lines in a semiconductor device 300, in accordance with a comparative embodiment of the present disclosure. FIG. 3A includes an upper plot showing a cross-sectional view of the semiconductor device 300 and a lower plot showing the distribution of the electric field lines during a switch-off state of the semiconductor device 300. Referring to the upper plot, the semiconductor device 300 includes an additional isolation region 302 arranged on a side of the gate dielectric layer 116 closer to the drain region 112. Each of the electric field lines represents a contour of areas with substantially equal voltage levels. In other words, the area with denser electric field lines implies a greater electric field in such area, and vice versa. During a switch-off state of the semiconductor device 300, the gate electrode 119, the source region 114 and the doped region 126 may be biased to a low voltage, e.g., zero volts, while the drain region 112 may be biased to a high voltage, e.g., about 30 volts. Referring to the lower plot, although the isolation region 302 can help increase the withstanding capability of the semiconductor device 300 against a relatively high drain voltage, the electric field line density is rather high around a corner of the isolation region 302. The likelihood of electrical breakdown may be increased around such corner due to a high voltage area around the corner of the isolation region 302. Further, the presence of the isolation region 302 extends the length of the channel where the carrier moves. As a result, the effective turn-on resistance Rds(ON) would be increased. Moreover, in order to accommodate the isolation region 302, the drain region 122 should be move farther from the gate electrode 119, and thus the device size of the semiconductor device 300 should be enlarged.

FIG. 3B shows a distribution of electric field lines in the HV transistor 100T, in accordance with some embodiments of the present disclosure. FIG. 3B includes an upper plot showing a cross-sectional view of the HV transistor 100T and a lower plot showing the distribution of the electric field lines during a switch-off state of the HV transistor 100T. Referring to the upper plot, the HV transistor 100T includes an additional conductive layer 152 arranged over the gate electrode 119 instead of the isolation region 302. During a switch-off state of the HV transistor 100T, the gate electrode 119, the source region 114 and the doped region 126 may be biased to a low voltage, e.g., zero volts, while the drain region 112 may be biased to a high voltage, e.g., about 30 volts. Referring to the lower plot, with help of the conductive layer 152, the electric field line density is rather high around the conductive layer 152, but is reduced around the gate dielectric layer 116. The conductive layer 152 can provide an additional section of the low voltage area in the HV transistor 100T, and therefore the electric field between the high-voltage drain terminal and the low-voltage gate electrode can be adjusted so that the areas with high voltages around the gate dielectric layer 116 can be reduced. The likelihood of electrical breakdown around the gate dielectric layer 116 may be decreased due to the smoothed electric field around the corner of the gate dielectric layer 116. Further, the absence of the isolation region 302 from the HV transistor 100T causes the effective channel to be shorter than that of the semiconductor device 300 while the high voltage withstanding capability is still maintained. As a result, the turn-on resistance Rds(ON) can be lowered and the turn-on current can be increased. Moreover, in the absence of the isolation region 302, the drain region 122 and the gate electrode 119 can be moved closer to each other, and the device size of the HV transistor 100T can be further decreased.

According to some embodiments, the high electrical resistance of the conductive line 252 is used to form a resistive element in a resistor-capacitor (RC) circuit associated with the NHV transistor 100N. The conductive layer 152 for the HV transistor 100T is arranged to be formed along with the formation of the conductive line 252 during the formation of the RC circuit for the NHV transistor 100N. The high-resistance conductive material used in forming the conductive line 252 can also be reused in forming the conductive layer 152 without difficulty. When compared to existing methods of forming HV transistors without the conductive layer 152, no cost is to be paid for providing an additional photomask for forming the conductive layer 152. Therefore, the processing cost and time can be reduced as compared to existing HV transistor structures.

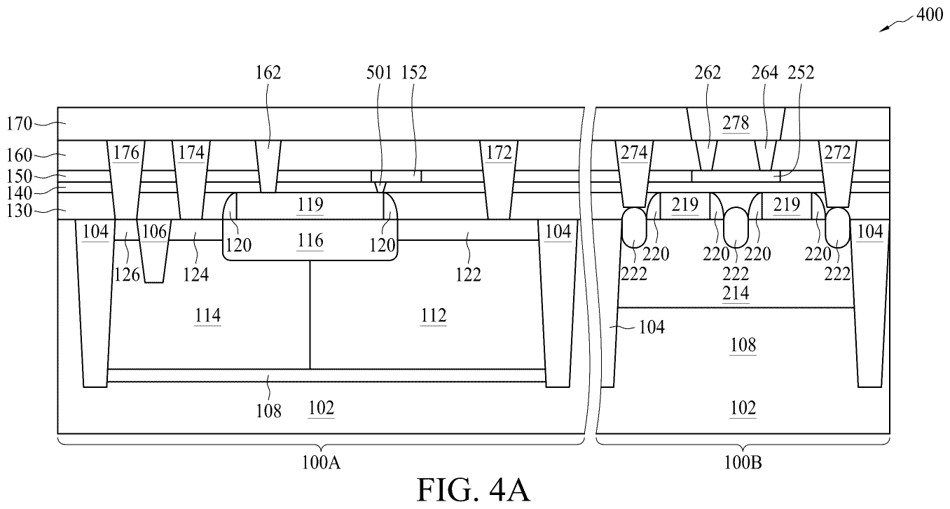

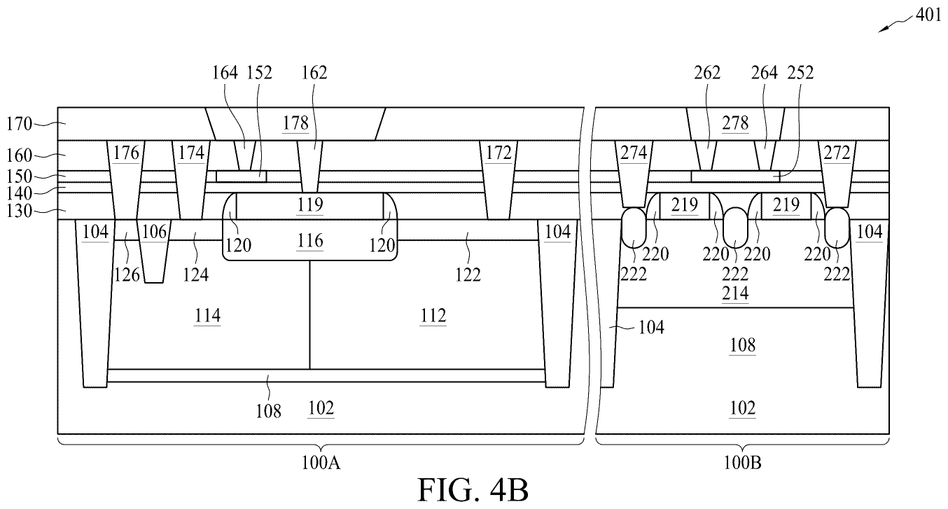

FIG. 4A shows cross-sectional view of a semiconductor device 400, in accordance with some embodiments of the present disclosure. The semiconductor device 400 is similar to semiconductor device 100 in many aspects, and thus these similar features are not repeated for brevity. The semiconductor device 400 is different from the semiconductor device 100 mainly in that the semiconductor device 400 includes a conductive via 501 formed in the first ILD layer 130 and electrically connecting the gate electrode 119 to the conductive layer 152. The material and method of forming for the conductive via are similar to those for forming the conductive via 162 or 164. The arrangement of the conductive via 501 can help reduce the routing area between the gate electrode 119 and the conductive layer 152. Therefore, more space in the interconnect structure 110 can be saved for other circuits.

FIG. 4B shows cross-sectional view of a semiconductor device 401, in accordance with some embodiments of the present disclosure. The semiconductor device 401 is similar to semiconductor device 100 in many aspects, and thus these similar features are not repeated for brevity. The semiconductor device 401 is different from the semiconductor device 100 mainly in that the conductive layer 152 of the semiconductor device 401 and the source region 114 are disposed on a same side of the gate electrode 119. The arrangement of the conductive layer 152 to be closer to the source region 114 than to the drain region 112 may help redistribute the electrical field around the corners of the gate dielectric layer 119 on one side of the source region 112. The overall risk of voltage breakdown of the semiconductor device 401 can be reduced accordingly. Further, although not separately illustrated, in another embodiment, a semiconductor device of the present disclosure can include two or more conductive layers, with a configuration and a material similar to the conductive line layer 152, arranged in the third ILD layer 150 or other suitable locations in the interconnect structure 110 to aid in redistribution of the electrical fields in the channel of the semiconductor device.

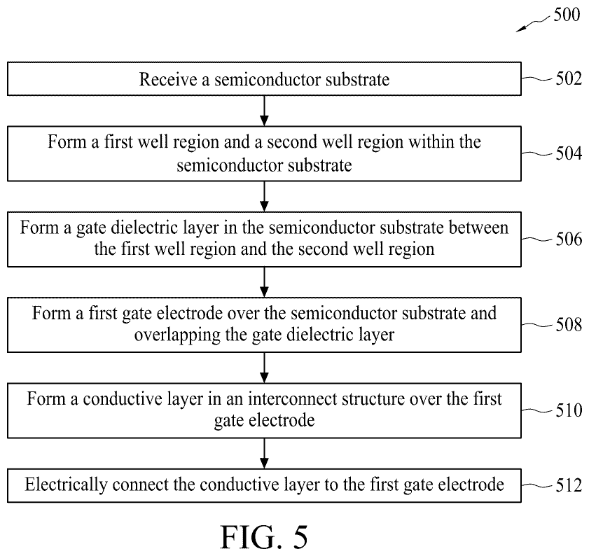

FIG. 5 shows a flowchart of a method 500 of manufacturing a semiconductor device, in accordance with some embodiments of the present disclosure. It shall be understood that additional steps can be provided before, during, and after the steps in method 800, and some of the steps described below can be replaced with other embodiments or eliminated. The order of the steps shown in FIG. 5 may be interchangeable. Some of the steps may be performed concurrently or independently.

At step 502, a semiconductor substrate is received. At step 504, a first well region and a second well region is formed within the semiconductor substrate.

At step 506, a gate dielectric layer is formed in the semiconductor substrate between the first well region and the second well region. At step 508, a first gate electrode is formed over the semiconductor substrate and overlapping the gate dielectric layer.

At step 510, a conductive layer is formed in an interconnect structure over the first gate electrode. At step 512, the conductive layer is electrically connected to the first gate electrode.

In accordance with some embodiments of the present disclosure, a method is provided. The method includes: receiving a semiconductor substrate; forming a first well region and a second well region within the semiconductor substrate; forming a gate dielectric layer in the semiconductor substrate between the first well region and the second well region; forming a first gate electrode over the semiconductor substrate and overlapping the gate dielectric layer; forming a conductive layer in an interconnect structure over the first gate electrode; and electrically connecting the conductive layer to the first gate electrode.

In accordance with some embodiments of the present disclosure, a method is provided. The method includes: receiving a semiconductor substrate; forming a first well region and a second well region within the semiconductor substrate; forming a gate dielectric layer in the semiconductor substrate between the first well region and the second well region; forming a first isolation region in the semiconductor substrate and laterally surrounded by the first well region; forming a first gate electrode over the gate dielectric layer and covering the gate dielectric layer from a top-view perspective; depositing a dielectric layer over the first gate electrode, the dielectric layer including a conductive layer overlapping the first gate electrode from a top-view perspective; and electrically connecting the conductive layer to the first gate electrode.

In accordance with some embodiments of the present disclosure, A semiconductor structure, comprising: a semiconductor substrate; a first well region and a second well region of a first conductivity and a second conductivity type, respectively, within the semiconductor substrate; a gate dielectric layer arranged in the semiconductor substrate between the first well region and the second well region; a first gate electrode arranged over the semiconductor substrate and overlapping the gate dielectric layer; a first interconnect structure arranged over the first gate electrode, the first interconnect structure comprising: a conductive layer overlapping the first gate electrode from a top-view perspective; and a conductive line adjacent to the conductive layer and electrically connecting the conductive layer and the first gate electrode.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a semiconductor substrate;
forming a first well region and a second well region within the semiconductor substrate;
forming a gate dielectric layer in the semiconductor substrate between the first well region and the second well region;
forming a first gate electrode over the semiconductor substrate and overlapping the gate dielectric layer;
forming a conductive layer in an interconnect structure over the first gate electrode; and
electrically connecting the conductive layer to the first gate electrode.

2. The method of claim 1, further comprising forming an isolation region in the semiconductor substrate and laterally surrounded by the first well region.

3. The method of claim 2, further comprising forming a source region within the first well region between the gate dielectric layer and the isolation region.

4. The method of claim 2, further comprising forming a drain region in the second well region on a side of the gate dielectric layer opposite to the isolation region.

5. The method of claim 4, wherein an electric field is generated between the drain region and the first gate electrode with the conductive layer during a switch-off state of a transistor associated with the first gate electrode.

6. The method of claim 2, wherein a vertical distance between a bottom surface of the conductive layer and a bottom surface of the gate dielectric layer is between about 1000 angstrom and about 1800 angstrom.

7. The method of claim 1, wherein the forming of the first gate electrode comprises forming a second gate electrode in the semiconductor substrate, wherein the first gate electrode and the second gate electrode are arranged in a first zone and a second zone, respectively, of the semiconductor substrate.

8. The method of claim 7, wherein the first gate electrode and the second gate electrode are associated with a planar transistor and a non-planar transistor, respectively.

9. The method of claim 7, the forming of the conductive layer comprises forming a conductive line over the second gate electrode, wherein the conductive layer and the conductive line are arranged in the same interconnect structure.

10. The method of claim 9, wherein the conductive layer and the conductive line are formed of the same material.

11. A method, comprising:
receiving a semiconductor substrate;
forming a first well region and a second well region within the semiconductor substrate;
forming a gate dielectric layer in the semiconductor substrate between the first well region and the second well region;
forming a first isolation region in the semiconductor substrate and laterally surrounded by the first well region;
forming a first gate electrode over the gate dielectric layer and covering the gate dielectric layer from a top-view perspective;
depositing a dielectric layer over the first gate electrode, the dielectric layer including a conductive layer overlapping the first gate electrode from a top-view perspective; and
electrically connecting the conductive layer to the first gate electrode.

12. The method of claim 11, further comprising forming a pair of second isolation regions in the semiconductor substrate, wherein the first well region, the second well region, the gate dielectric layer and the first isolation region are arranged between the pair of second isolation regions.

13. The method of claim 11, wherein electrically connecting the conductive layer to the first gate electrode comprises depositing a conductive line to electrically connect the conductive layer and the first gate electrode, wherein the conductive layer and the conductive line have different materials.

14. The method of claim 11, further comprising forming a second gate electrode over the semiconductor substrate, wherein the first gate electrode and the second gate electrode are associated with a first-type transistor and a second-type transistor, and the first-type transistor operates under a first biasing voltage greater than a second biasing voltage under which the second-type transistor operates.

15. The method of claim 14, wherein the depositing of the conductive layer comprises depositing a conductive line over the second-type transistor, wherein the conductive layer and the conductive line are deposited by a same operation.

16. The method of claim 15, wherein the conductive line is configured as a resistive element associated with the second-type transistor.

17. The method of claim 11, wherein the first gate electrode comprises two opposite lateral sides, and the conductive layer overlaps only one of the two opposite lateral sides from a top-view perspective.

18. A semiconductor structure, comprising:
a semiconductor substrate;
a first well region and a second well region of a first conductivity and a second conductivity type, respectively, within the semiconductor substrate;
a gate dielectric layer in the semiconductor substrate between the first well region and the second well region;
a first gate electrode over the semiconductor substrate and overlapping the gate dielectric layer;
a first interconnect structure over the first gate electrode, the first interconnect structure comprising:
a conductive layer overlapping the first gate electrode from a top-view perspective; and
a conductive line electrically connecting the conductive layer and the first gate electrode.

19. The semiconductor structure of claim 18, wherein the conductive layer and the conductive line are formed of different materials.

20. The semiconductor structure of claim 18, further comprising:
a second gate electrode arranged over the semiconductor substrate, wherein the first gate electrode and the second gate electrode are associated with a first-type transistor and a second-type transistor, respectively,
wherein the first interconnect structure further comprises a resistive element, and the conductive layer and the resistive element are formed of a same high-resistance material.
